(19) United States
(12) Patent Application Publication
(10) Pub. No.: US 2020/0035482 A1
(43) Pub. Date: Jan. 30, 2020

(54) Buffer layer for Gallium Nitride-on-Silicon epitaxy

(71) Applicants: Jeff C. Ramer, Dublin, CA (US); Karl M. Knieriem, Hayward, CA (US)

(72) Inventors: Jeff C. Ramer, Dublin, CA (US); Karl M. Knieriem, Hayward, CA (US)

(21) Appl. No.: 16/510,547

(22) Filed: Jul. 12, 2019

Related U.S. Application Data
(60) Provisional application No. 62/703,620, filed on Jul. 26, 2018.

(51) Int. Cl. H01L 21/02; C30B 29/06; C30B 29/40; C30B 25/18; C23C 16/34; C23C 16/455

(52) U.S. Cl. CPC H01L 21/0251; H01L 21/02381; H01L 21/02433; H01L 21/02458; H01L 21/02507; H01L 21/0254; H01L 29/155; C30B 29/06; C30B 29/406; C30B 25/183; C23C 16/34; C23C 16/45525; H01L 21/0262

(57) ABSTRACT

Embodiments generally relate to multi-layer buffer structures on silicon. One method for forming such a structure comprises: providing a (111) silicon substrate; using ALD to deposit a first layer of AlN on the substrate; using first and second precursor materials at a first V-III ratio to deposit a plurality of AlN islands forming a second layer on the first layer; using the first and second precursor materials at a second V-III ratio, to deposit a third layer of AlN overlying and in contact with the islands and the first layer between the islands, forming domains; and using the first and second precursor materials at a third V-III ratio, to deposit a fourth layer of AlN on the third layer. All depositions occur at one predetermined temperature range. The fourth layer is characterized by a fourth layer top surface that is anatomically smooth.

### CROSS REFERENCES TO RELATED APPLICATIONS

This application claims priority from U.S. Provisional Patent Application Ser. No. 62/703,620 filed on Jul. 26, 2018, which is hereby incorporated by reference as if set forth in full in this application for all purposes.

### FIELD OF INVENTION

This invention relates in general to the field of epitaxial growth of Gallium Nitride on Silicon, and in particular to the growth of buffer layers between the substrate and the epitaxial layer.

### BACKGROUND

Gallium nitride (GaN) is a Group III/Group V compound semiconductor material with a wide, direct bandgap (3.4 eV). It has optoelectronic, as well as other applications. Like other Group III nitrides, GaN has a low sensitivity to ionizing radiation, and so is useful in solar cells. GaN is also useful in the fabrication of blue light-emitting diodes (LEDs) and lasers. Unlike previous indirect bandgap devices (e.g., silicon carbide), GaN LEDs are bright enough for daylight applications. GaN devices also have application in high power and high frequency devices, such as power amplifiers.

GaN LEDs and GaN-based devices are conventionally fabricated using a metalorganic chemical vapor deposition (MOCVD) for deposition on sapphire or silicon carbide (SiC) substrate with great success, even though these substrates are expensive to make, and their small size also drives fabrication costs.

On the other hand, while there are many patents and research papers describing GaN-on-Si processes involving the use of buffer structures, very limited success has been achieved in this field, resulting in GaN-on-Si technologies having a relatively small impact on the market.

Nevertheless, products made with GaN on Silicon wafers have some clear advantages, as they not only benefit from the use of large yet cheaper high-quality substrate material, but also leverage the advancements of the IC industry using single wafer production using 6″ to 18″ Silicon substrates. Most of sapphire LED manufacturers, in contrast, are still using obsolete 2″ or 4″ production equipment.

There are two fundamental problems associated with GaN-on-Si device technology. First, as FIG. 1 shows, there is a lattice mismatch between Si and GaN. The difference in lattice constants between GaN and Si results in a high density of defects from the generation of threading dislocations. This problem is normally addressed by using a buffer layer of AlN, InGaN, AlGaN, or the like, prior to the growth of GaN. The buffer layer provides a transition region between the GaN and Si.

An additional and more serious problem exists with the use of Si, as there is also a thermal mismatch between Si and GaN. GaN-on-sapphire experiences a compressive stress upon cooling. FIG. 2 is a graph depicting the thermal expansion coefficients (TECs) of GaN, Si, SiC, AlN, and sapphire. Film cracking has been a serious issue for GaN-on-Si, which is under tensile stress upon cooling, causing the film to crack when the film is cooled down from the high deposition temperature. The thermal expansion coefficient mismatch between GaN and Si is about 54%.

The film cracking problem has previously been analyzed in depth, and several methods have been tested, achieving different degrees of success. The methods used to grow crack-free layers can be divided into 4 groups.

(1) Substrate modification: Some approaches have employed patterned Si (as in German Patent DE10,056,645), bubbled Si (as in U.S. Pat. No. 8,008,181) or an engineering substrate with Si surface, hoping to reduce the stress created by the large mismatch of thermal expansion coefficients. Generally, no real benefits are achieved, because the problem of how to grow high quality (defect-free) GaN materials is not addressed.

(2) Interlayer: Some approaches (such as those in U.S. Pat. Nos. 9,142,723 and 7,612,361) have employed some forms of interlayers (i.e. SiNₓ or SiO₂) for lateral growth or crack filling. Metal transition layers have also been tried in the hope of somehow decoupling the grown films from the substrate. These approaches require thicker layers of GaN to be grown, and exacerbate the issues caused by mismatched thermal expansion coefficients between the grown material and Silicon substrate.

(3) Cycling multi-layer: Some (e.g. U.S. Pat. No. 7,910,937) have proposed multi-layer buffer structures, such as cycling AlN/GaN bi-layer or AlN/AlGaN superlattices. The hope is that stress will somehow be reduced by introducing a cyclic lattice mismatch. However, the quality of the materials is not improved by cycling the lattice constants.

(4) Graded AlGaN buffer structure: Some have tried an initial AlN layer followed by a graded or stepped AlGaN layer (e.g. U.S. Pat. No. 7,598,108), but have had little success in addressing either the lattice mismatch or the TEC mismatch.

It was generally thought that the buffer layer would mitigate the stress of the material system and the reduction of dislocation due to the lattice mismatch. The real working mechanism of stress relief was never understood. The fallacy that the material stress can be somehow reduced by the buffer layers, while maintaining high crystal quality, led to repeated failures of Ga-on-Si commercialization.

There is, therefore, a need for new methods for growing buffer layers for use in GaN on Silicon devices, that avoid depositing multiple AlN layers with different density deposited at very different temperature ranges, such deposition processes having been shown to yield low quality layers of undesirably large thicknesses.

### SUMMARY

Embodiments generally relate to multi-layer buffer structures formed on silicon substrates, and methods for forming such structures.

In one embodiment, a method for forming a multi-layer AlN buffer structure on silicon comprises: providing a (111) oriented Silicon substrate having a top surface; using atomic layer deposition to deposit, at a predetermined temperature range, a first layer of AlN on the top surface; using first and second precursor materials, characterized by a first V-III ratio, to deposit, at the predetermined temperature range, a plurality of AlN islands forming a second layer overlying and in contact with the first layer; using the first and second precursor materials, characterized by a second V-III ratio, to deposit, at the predetermined temperature range, a third layer of AN, the third layer overlying and in contact with the islands and the first layer between the islands, forming domains; and using the first and second precursor materials, characterized by a third V-III ratio, to deposit, at the predetermined temperature range, a fourth layer of AlN, the fourth layer overlying and in contact with the third layer. The fourth layer is characterized by a fourth layer top surface that is anatomically smooth.

In another embodiment, a method comprises: providing a (111) oriented Silicon substrate having a top surface; forming on the top surface, at a first temperature range, a first multilayer buffer structure comprising AlN films; forming on top of the first multilayer buffer structure, at a second temperature range, a second multilayer buffer structure comprising AlGaN films; and growing, at a third temperature range, a first epitaxial GaN layer directly overlying and in contact with the second multilayer buffer structure; wherein forming the first multilayer buffer structure comprises: using atomic layer deposition to deposit a first layer of AlN overlying and in direct contact with the top surface;using first and second precursor materials, characterized by a first V-III ratio, to deposit a plurality of AlN islands forming a second layer overlying and in contact with the first layer; using the first and second precursor materials, characterized by a second V-III ratio, to deposit a third layer of AlN, the third layer overlying and in contact with the islands and the first layer between the islands, forming domains; and using the first and second precursor materials, characterized by a third V-III ratio, to deposit a fourth layer of AlN, the fourth layer overlying and in contact with the third layer. The fourth layer is characterized by a fourth layer top surface that is anatomically smooth, Forming the second multilayer buffer structure comprises: forming an AlₓGa1-xN layer directly overlying and in direct contact with the fourth layer of AlN, where 0<x=<0.9; and forming an AlyGa1-yN layer directly overlying and in contact with the AlₓGa1-xN layer, where y<=x.

In another embodiment, a multi-layer buffer structure for high quality GaN on a (111) silicon substrate comprises: a first AlN layer overlying and in direct contact with the silicon substrate; a second AlN layer overlying and in direct contact with the first AlN layer; a third AlN layer overlying and in direct contact with the second AlN layer; a fourth AlN layer overlying and in direct contact with the third AlN layer; and a first AlGaN layer overlying and in direct contact with the fourth AlN layer, the first AlGaN layer having a top surface suited for the growth thereupon of high quality GaN, The second AlN layer comprises multiple crystal domains formed by island growth over the first AlN layer.

### BRIEF DESCRIPTION OF DRAWINGS

FIG. 1 (Prior art) Lattice constants of various materials

FIG. 2 (Prior art) Thermal expansion coefficients of various materials

FIG. 3 (Prior art) Effect of compressive and tensile stress

FIG. 4 (Prior art) A schematic cross-section view of a GaN-on-Silicon device structure

FIG. 5 illustrates a setup for buffer layer growth according to one embodiment of the present invention.

FIG. 6A illustrates a cross-section view through the setup of FIG. 5 during the first step of deposition according to one embodiment of the present invention.

FIG. 6B illustrates a cross-section view through the setup of FIG. 5 during the second step of deposition according to one embodiment of the present invention.

FIG. 6C illustrates a cross-section view through the setup of FIG. 5 at an early stage of the third step of deposition according to one embodiment of the present invention.

FIG. 6D illustrates a cross-section view through the setup of FIG. 5 at a later stage of the third step of buffer layer deposition according to one embodiment of the present invention.

FIG. 6E illustrates a cross-section view through the setup of FIG. 5 during the fourth step of deposition according to one embodiment of the present invention.

FIG. 7A shows an AFM image of an AlN surface after the second step of deposition according to one embodiment of the present invention.

FIG. 7B shows an AFM image of an AlN surface after the third step of deposition according to one embodiment of the present invention.

FIG. 7C shows an AFM image of an AlN surface after the fourth step of deposition according to one embodiment of the present invention.

FIG. 8A illustrates a cross-section view during the growth of a first AlGaN transition layer according to one embodiment of the present invention.

FIG. 8B illustrates a cross-section view during the growth of a second AlGaN transition layer according to one embodiment of the present invention.

FIG. 8C illustrates a cross-section view during the growth of a GaN layer over the structure shown in FIG. 8B, according to one embodiment of the present invention.

FIG. 8D illustrates a cross-section view during a cool down stage after the GaN growth step of FIG. 8C, according to one embodiment of the present invention.

FIG. 9 illustrates XRD correlation between GaN and AlN

FIG. 10 illustrates XRD comparison with prior art

FIG. 11 is a flowchart of process steps to form a multi-layer buffer structure of AlN according to one embodiment of the present invention.

FIG. 12A illustrates a device structure including a multi-layer buffer structure fabricated according to the process of FIG. 11, followed by stepped AlGaN transition layers before a final GaN layer.

FIG. 12B illustrates another device structure including a multi-layer buffer structure fabricated according to the process of FIG. 11, followed by graded AlGaN transition layers before a final GaN layer.

FIG. 13 illustrates a device structure including a multi-layer buffer structure fabricated according to the process of FIG. 11, followed by stepped AlGaN transition layers before a final AlGaN layer.

FIG. 14 illustrates a cross section view of an LED based on the device structure of FIG. 11B.

FIG. 15 illustrates a cross section view of a HEMT based on the device structure of FIG. 11B.

### OVERVIEW

In the present invention, the solution to growing high quality GaN film on Silicon substrate relies on two intertwined strategies: (1) growing very thin overall AlN/AlGaN/GaN material systems with the quality needed for state-of-art device performances and (2) managing the stress between growth temperature and room temperature without, as will be explained below, focusing on attempting to reduce the stress of each layer.

The thermal strain created by the difference of thermal expansion coefficient and change of the temperatures between the growth temperature and the room is described in Equation 1:

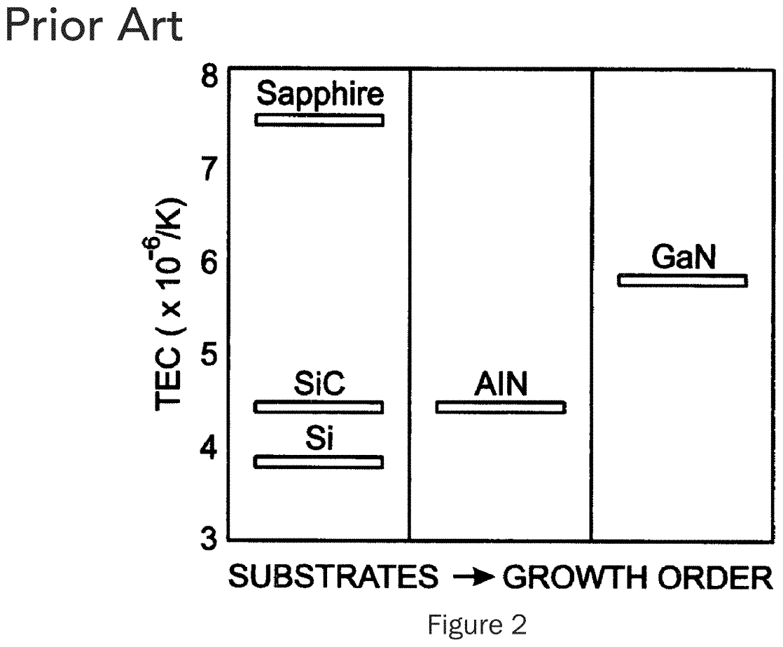

e_{T}=(α_{f}−αₛ)(T_{g}−Tₒ) Eq. 1

where e_{T} is the thermal strain, α_{f} and αₛ are the thermal expansion coefficients of GaN and Si, and T_{g} and Tₒ are the growth temperature and the room temperature. From FIG. 2, α_{f}>αₛ meaning GaN film contracts faster than Silicon, so the thermal strain is always tensile.

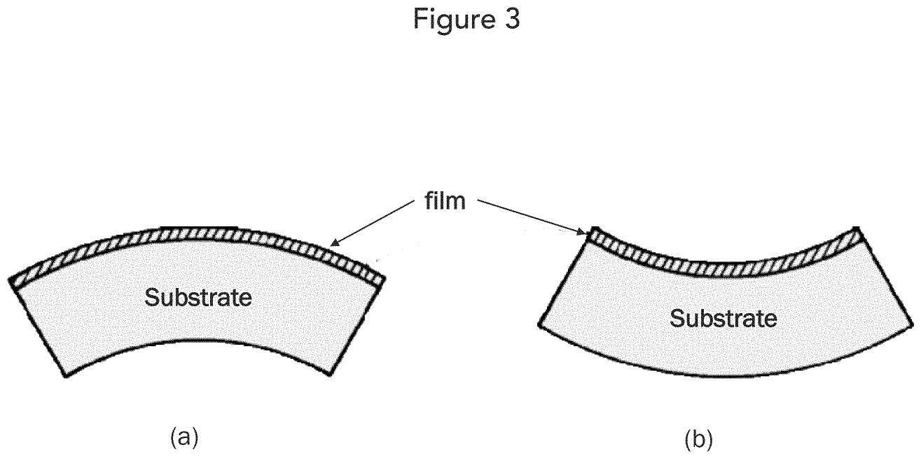

The wafer warpage caused by the strain is given by Stoney equation:

$$k = \frac{6 {h}_{f} ( 1 - {v}_{s} ) {σ}_{T}}{{E}_{s} {h}_{s}^{2}} \qquad Eq . 2$$

where k is the curvature (1/Radius) of substrate warpage, h_{f} and hₛ are the thicknesses of GaN and Silicon substrate, Eₛ and vₛ are Young's modulus and Poison's ratio of the silicon substrate, and σ_{T}E=_{f} e_{T} is the thermal stress, with E_{f} as the Young's modulus of GaN film. As shown in FIG. 3, the substrate will curve down at the periphery when compressive stress is present in the film at the substrate-film interface, and curve up at the periphery when tensile stress is present in the film at the substrate-film interface. When the film is under strong tensile stress, the film can easily crack or peel.

From Equation 2, as the GaN film thickness increases, the substrate warpage change induced when cooling down the material will increase correspondingly. Equation 2 does not describe the complete picture, because it does not include the wafer warpage at the growth temperature caused by the lattice mismatch between GaN and Si.

If a GaN film could somehow be grown with the “right” amount, k_{f}, of compressive strain, it can offset the tensile strain when cooling, resulting adequate compression strain at room temperature.

$$k = \frac{6 {h}_{f} ( 1 - {v}_{s} ) {σ}_{T}}{{E}_{s} {h}_{s}^{2}} - {k}_{f} \qquad Eq . 3$$

If the GaN related material (AlGaN, InGaN, etc) grown as a film on a substrate is too thick, regardless of how the buffer structure works, the TEC mismatch will cause that material to contract far more than silicon substrate, leading to tensile stress when the wafer is cooled to room temperature. Severe tensile stress can cause peeling of the films. On the other hand, if a very thick film is grown, very high compressive stress will occur at the growth temperature, which is close to 1000° C. Such high compressive stress in the film is translated to very high tensile stress in the substrate, which is weaker at high temperature, so the substrate may crack or shatter.

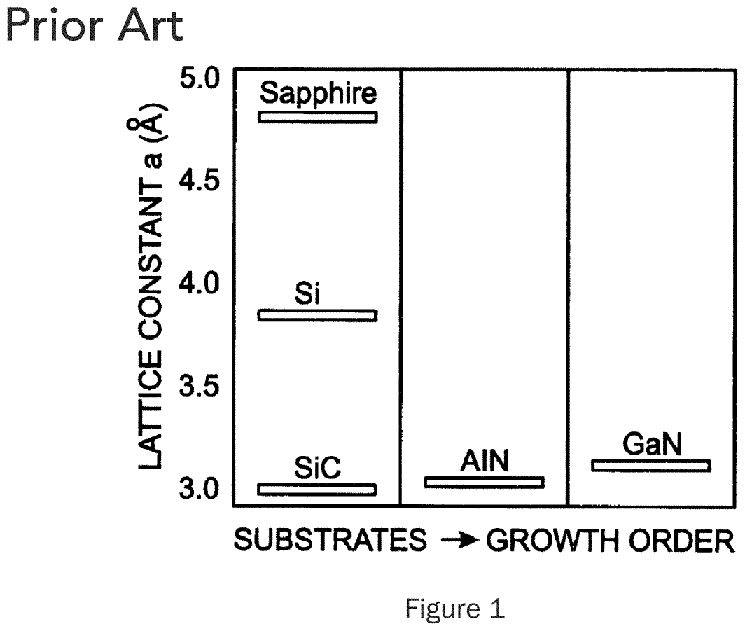

From FIG. 1, the lattice constant of Si at (111) surfaces is larger than those of AlN and GaN. Therefore, growing these layers onto Si following the crystal structure of Si will result in atomic forces that try to reduce the surface area. This contracting force will cause the Si substrate to bow up, creating tensile stress to the grown film.

In the absence of a creative solution, such as those presented below in this disclosure, the tensile stress of the grown film and the tensile stress due to mismatch of the thermal expansion coefficient would only add up into very high tensile stress to the film.

However, referring to FIG. 1, the lattice constant of AlN is smaller than that of GaN. If we were to be able to grow a thin AlN layer to recover its own native lattice constant, the subsequent GaN layer would evolve to build compressive strain (k_{f} in Equation 3) high enough to offset the tensile thermal strain. As long as the thickness of GaN does not exceed a critical value implied by Equation 3, such situations can be accomplished. As the combined results of the stress management and the quality of AlN layers, crack free GaN layers could be successfully deposited on (111) silicon substrate with various diameters.

This innovative approach of focusing on stress management (rather than stress relaxation) would create a window for compressive or low strain GaN film grown on Silicon substrate by MOCVD. However, the prerequisite of such success is the ability to grow very high quality thin AlN layers.

In the present invention, a unique growth sequence is used to deposit different types of AlN layers. This approach should not be confused with the prior art approach of using several AlN layers with different density deposited at very different temperature ranges. In fact, the experimental data show drastically different results in term of the quality of materials and required thicknesses between these two approaches.

### DETAILED DESCRIPTION

(111) oriented Silicon substrates are typically used for growing GaN materials because (111) Si exhibits a 3-fold symmetry which is needed as a template for hexagonal crystal structure of GaN. However, one cannot grow GaN directly on Si substrates because Ga and Si can form an alloy in its liquid phase at growth temperature above about 800 C. A buffer layer, also serving as material barrier, is needed to avoid this destructive phenomenon. The buffer layer typically begins with an initial AlN layer to seal the silicon surface to avoid any exposure of Silicon to Ga.

The importance of the quality of the AlN in the buffer layer was not previously realized in terms of its influence on the crystal quality of GaN subsequently deposited on top of the buffer layer. Generally, the AlN starting layer has been used simply as a sealing layer, preventing silicon from forming a Si—Ga alloy that could lead to defect formations. It has also not been previously understood that the bonding between the AlN layer and silicon is extremely important for eliminating cracking of the grown films after cooling down.

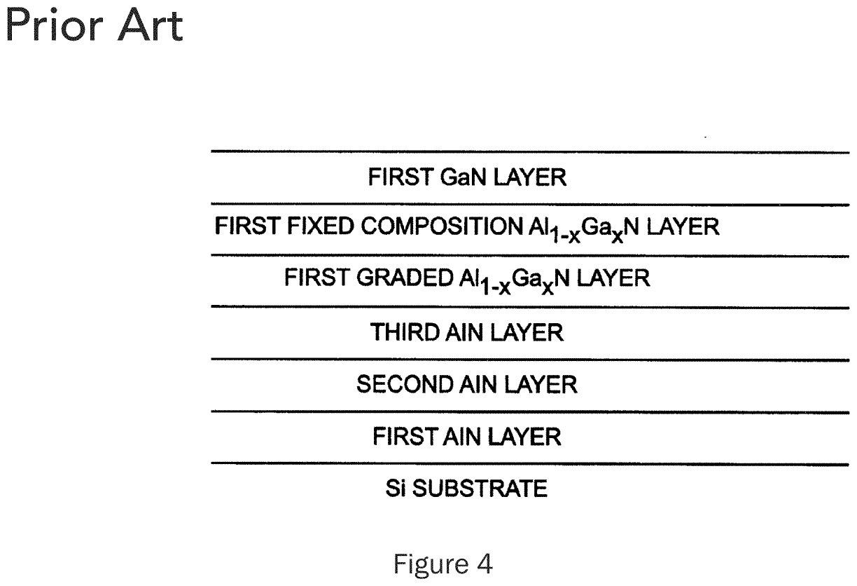

FIG. 4 shows a prior art example, described in U.S. Pat. No. 7,598,108, where 3 layers of AlN, deposited at 2 temperature ranges and having two different densities, have been used to reduce the stress. The first and the third AlN layers are deposited at much higher temperatures than the second AlN layer. The quality of AlN deposited at a temperature lower than 1000° C. is usually very poor. The surface mobility of Al atoms at such low temperatures is very poor. The growth is more like low-temperature chemical vapor deposition (CVD), rather than epitaxy. Once a poor quality AlN layer is deposited, a very thick AlN layer is needed to gradually improve its crystalline quality. This low-temperature AlN layer therefore limits the crystal quality of the subsequently-grown GaN.

In the present invention, 4 layers of AlN layers are epitaxially deposited, the first being an ALD layer, and the next three being grown at the same temperature range as was the first but with different growth modes. These growth modes result in very high tensile stress in the AlN layer stack, which has been discovered to be beneficial for the stress management of the whole device structure from the silicon substrate through to the final epitaxial GaN layer.

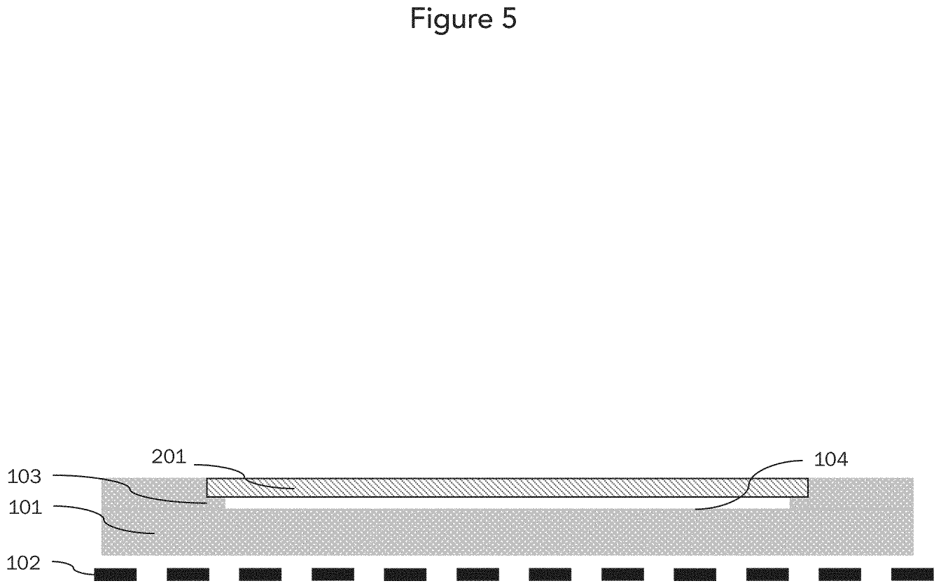

FIG. 5 shows a setup for multi-layer growth of films (such as AlN, AlGaN, GaN, InGaN etc.) on a silicon substrate. This may be performed within a MOCVD system, for example.

The growth substrate 201 is (111) Silicon which is placed on a wafer carrier 101 and is heated by the heater coil 102 to a temperature range between 1000° C. to 1200° C. during growth of the AlN layers. Typically, the (111) Silicon substrate has small offcut angles to create steps on the surface. These steps (also called kinks) provide energetically favorable sites for depositing atoms to attach. Under certain growth conditions, these steps help to produce what is defined for the entirety of this disclosure as “layer growth”, in which the epitaxial growth extends the steps laterally, thus layer by layer. Layer growth is characterized by flow patterns which can be observed by atomic force microscopy (AFM). Because the grown AlN has a lattice constant smaller than that of Si, the resulting grown AlN material tends to pull atomic distance closer, resulting in bowing downward of the central region of the silicon substrate 201 as the thickness of AlN increases. Therefore, there is a need to have a pedestal 103 to raise the silicon substrate so that most of the silicon wafer is suspended above the floor 104 of the wafer carrier. The thicknesses of silicon substrates are typically in the range of 0.5 mm to 3 mm and the diameters are in the range of 50 mm to 450 mm. The initial gap between the silicon wafer 201 and the floor 104 is in the range of 0.005 mm to 0.4 mm.

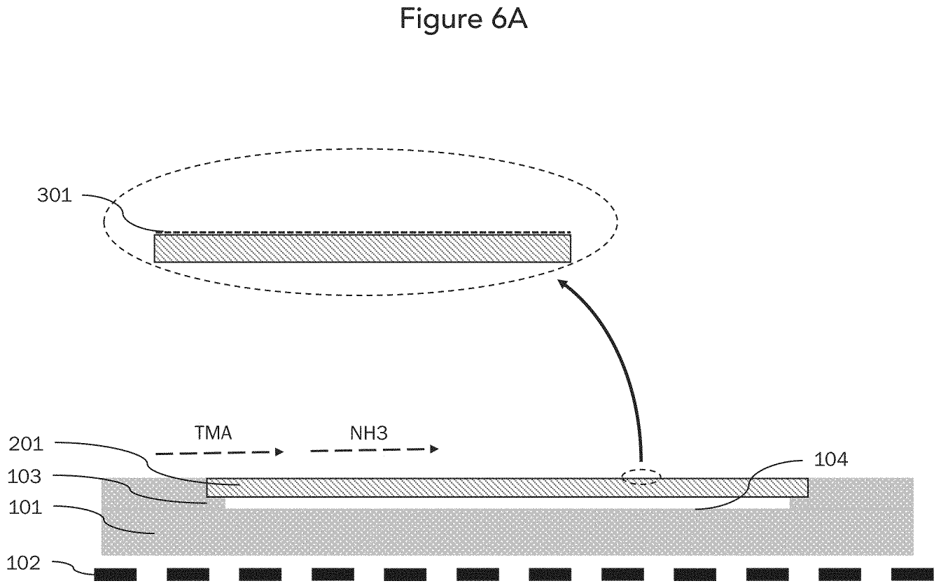

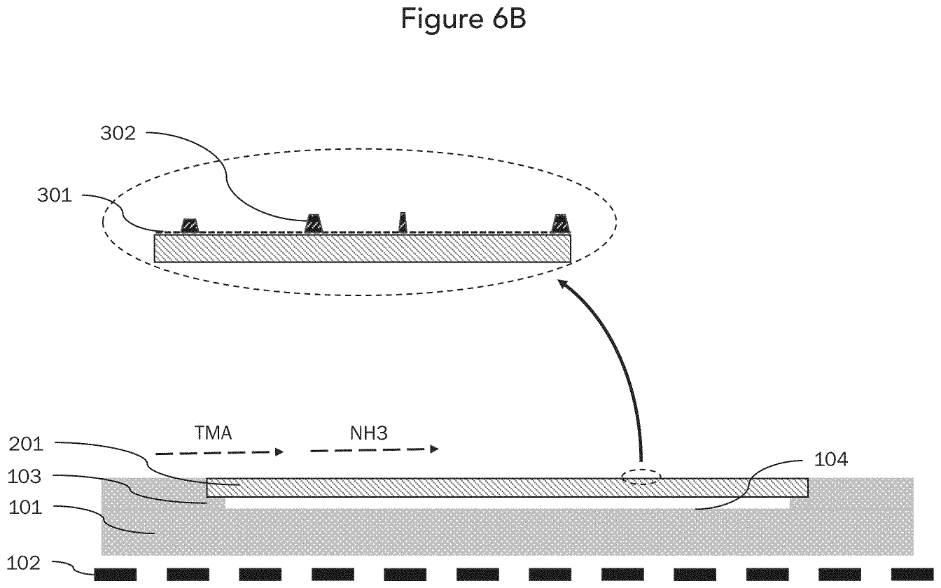

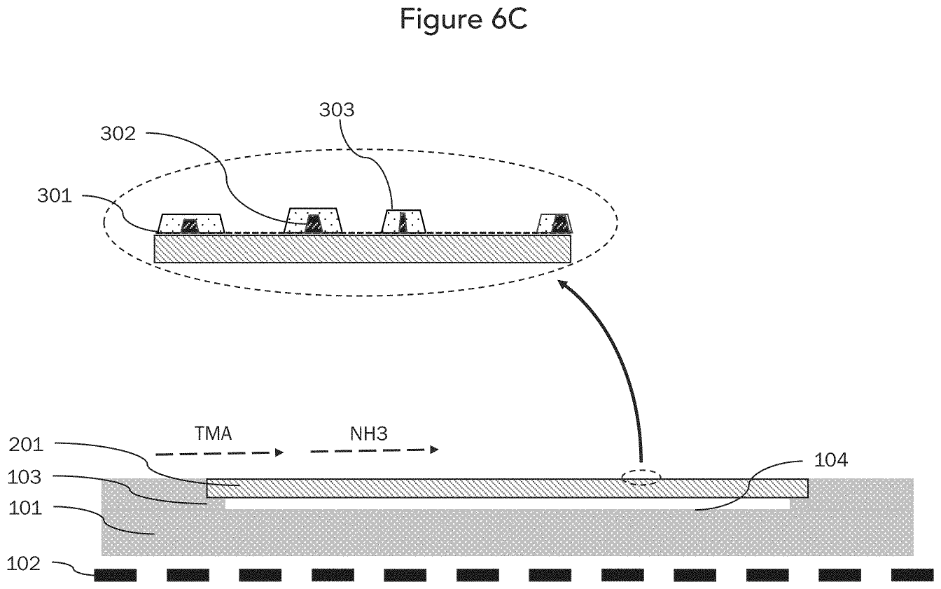

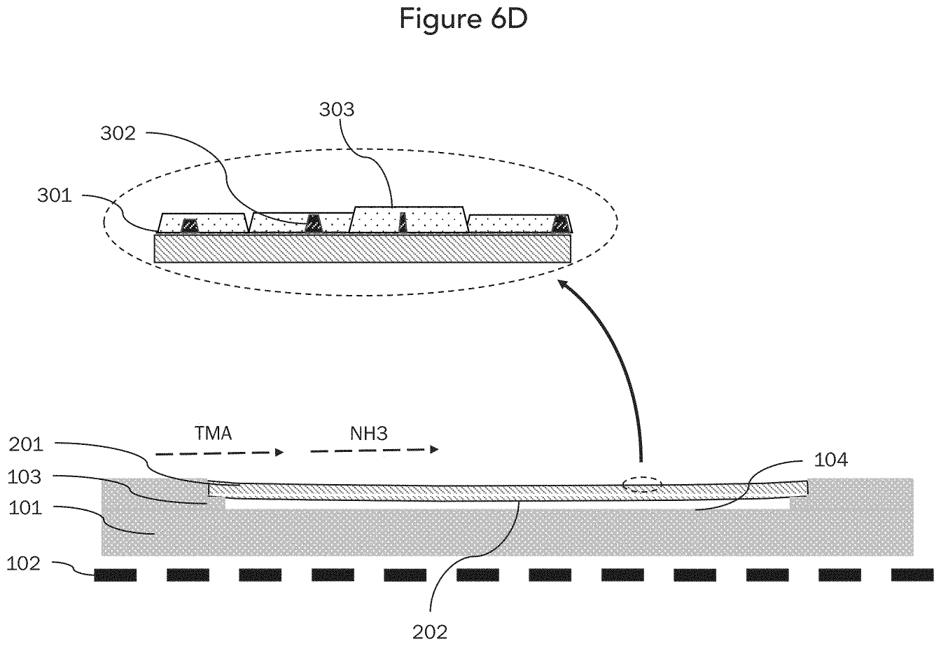

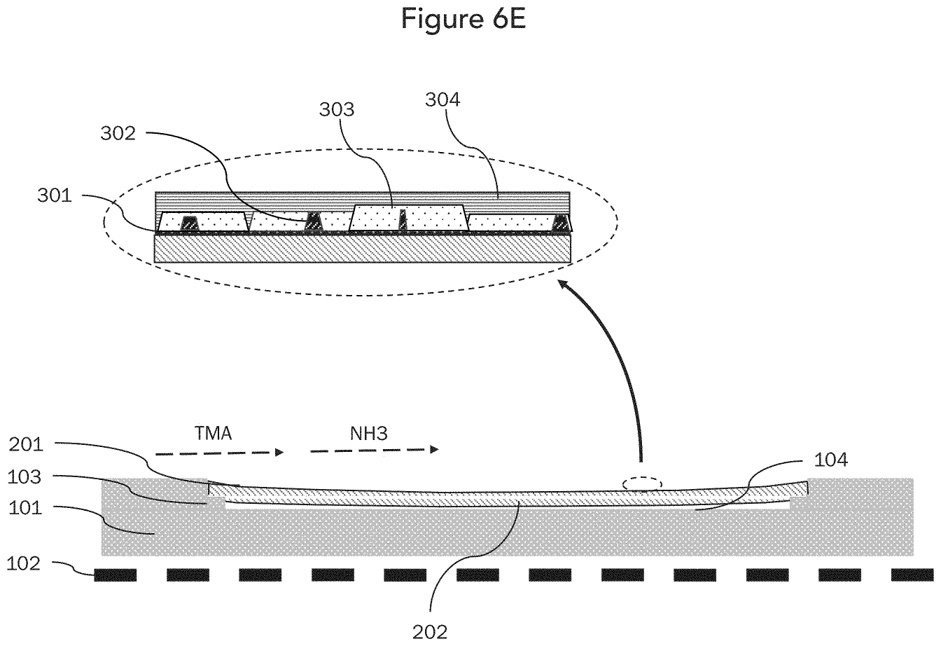

As shown in FIG. 6A the initial AlN nucleation layer is deposited by atomic layer deposition (ALD) in which the group V material (typically N in the form of NH₃) and the group III material (typically in the form of Trimethyl-Aluminum or TMA) are introduced into the growth chamber in succession. This initial sequence results in a layer 301, 1 to 10 atomic layers thick, of AlN. This layer is very important in sealing the Silicon surface from further NH₃ exposure to grow SiNₓ . SiNₓ was proposed by many groups to serve as mechanism to encourage lateral growth of AlGaN materials. But, the strain relaxation from such growth prohibits compressive strain to build up for strain management as described previously. The first AlN nucleation layer not only seals the Silicon surface, it also provides a foundation for stress buildup in the subsequent growth of AlN which will become apparent in the latter description.

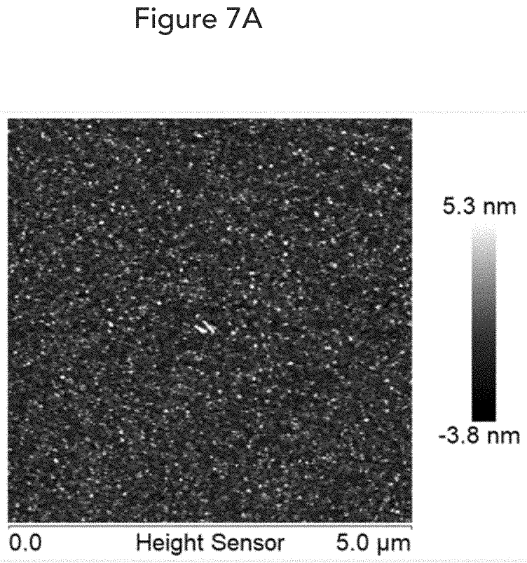

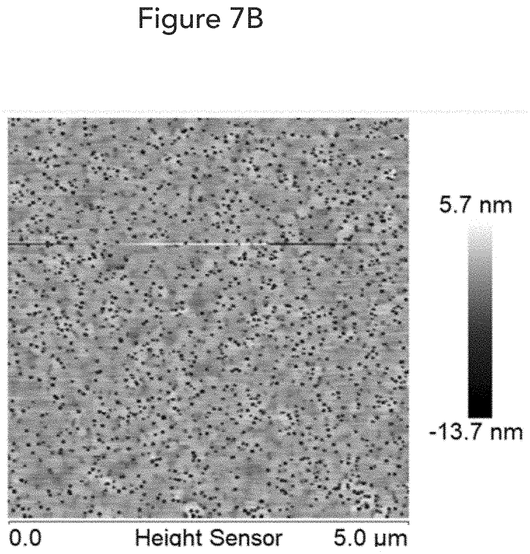

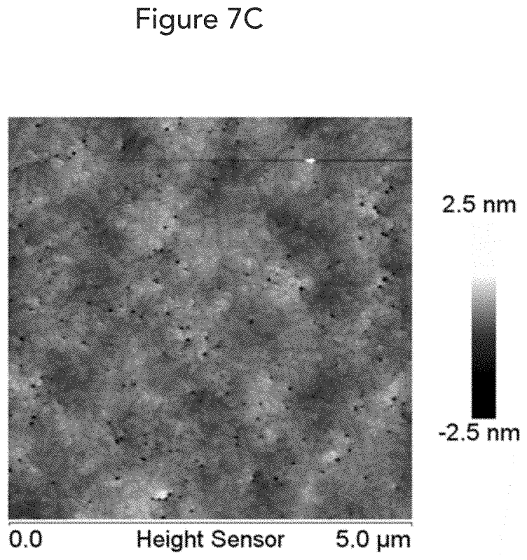

After the initial nucleation layer is formed, both TMA and NH₃ are introduced to the system simultaneously with a very small TMA flow rate compared with NH₃ (so-called V-III ratio). Under this condition, the mobility of TMA radicals is greatly enhanced so that the atoms move along the surface. This mobility allows the atoms to bond with each other while minimizing the material system energy. In such a condition, the growth is switched from an atomic layer growth mode to an island growth mode (3D growth) as shown in FIG. 6B. The initiation of islands 302 is through random nucleation at kinks on the surface, followed by migration of atoms toward the kinks. People who are skilled in the art understand the physics behind such growth mode. The surface morphology measured by atomic force microscope (AFM) is depicted in FIG. 7A. AFM is an extremely sensitive measurement technique that uses a probe rastering above the surface and controls the tunneling current between the probe and the surface.

The plurality of islands 302 make up what is termed for the entirety of this disclosure a second layer of AlN, although it does not form a continuous film like underlying first layer 301, and therefore results in a very rough surface. Because the stress of the film is localized, it does not apply significant stress to the substrate. Also, referring to FIG. 6B, the island sizes are not uniform, and the height of these island ranges from 3 nm to 15 nm.

After depositing the AlN islands, the V-III ratio is changed from that used for the island-growing process described above, lowering it to a value that increases the lateral growth rate and reduces the vertical growth rate. In this lateral growth mode, the areas of islands expand laterally into larger domains 303 as shown in FIG. 6C. At the beginning of this process of lateral growth, the AlN materials remain discontinuous and do not apply significant stress to the substrate.

As the lateral growth mode continues, the AlN domains 303 begin to coalesce. These form grain boundaries and many dislocations are generated. As the AlN material forms continuous coverage of the surface, the strain of this third AlN layer begins to apply stress to the substrate and the substrate begins to bow downward 202 as shown in FIG. 6D. As the same time, the surface morphology becomes continuous as depicted in the inset in FIG. 6D and in the AFM in FIG. 7B, where the islands disappear into continuous layer 303.

When the Silicon substrate begins to bow downward as the indicator of completion of AlN coverage, the growth mode of AlN is switched to 2D layer growth mode by further decreasing the V-III ratio, forming a fourth AlN layer 304. Under such growth conditions, the surface of AlN gradually becomes smooth and, at the same time, a significant stress from the combination of the first, second, third and fourth layers of AlN is applied to the silicon substrate. Significant substrate warpage results, as shown in FIG. 6E; this can be measured by an in-situ deflectometer.

The smooth morphology of the final AlN film 304 is depicted in FIG. 7C, with a height scale of +/−2.5 nm. The observed low-density pits are less than 1 nm deep and a flow pattern can be seen indicating smoothness at an atomic level.

After the final (fourth) AlN layer, the structure is ready for the deposition of AlGaN layers prior to the deposition of the final desired GaN layer.

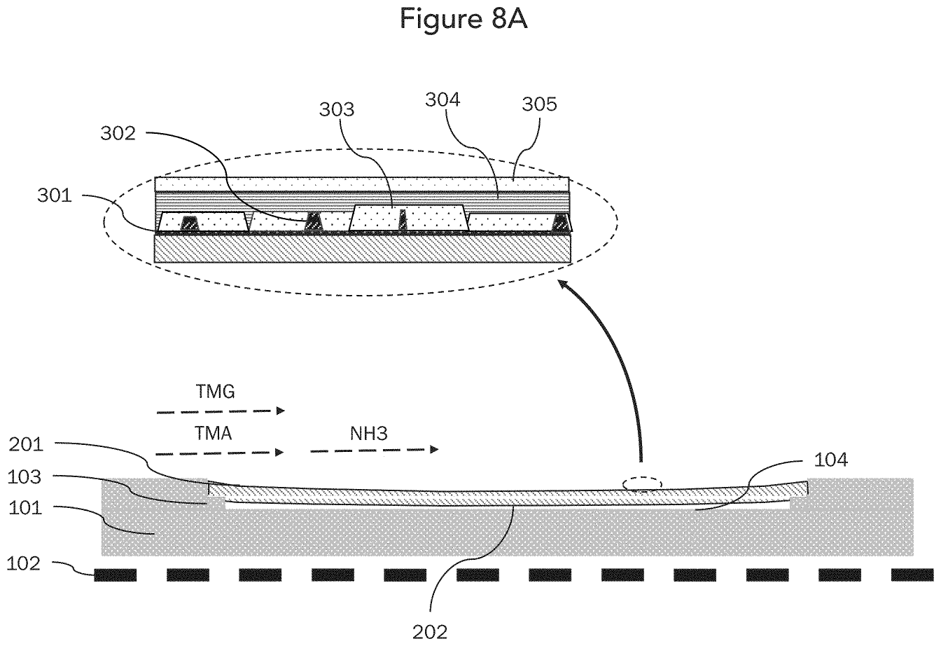

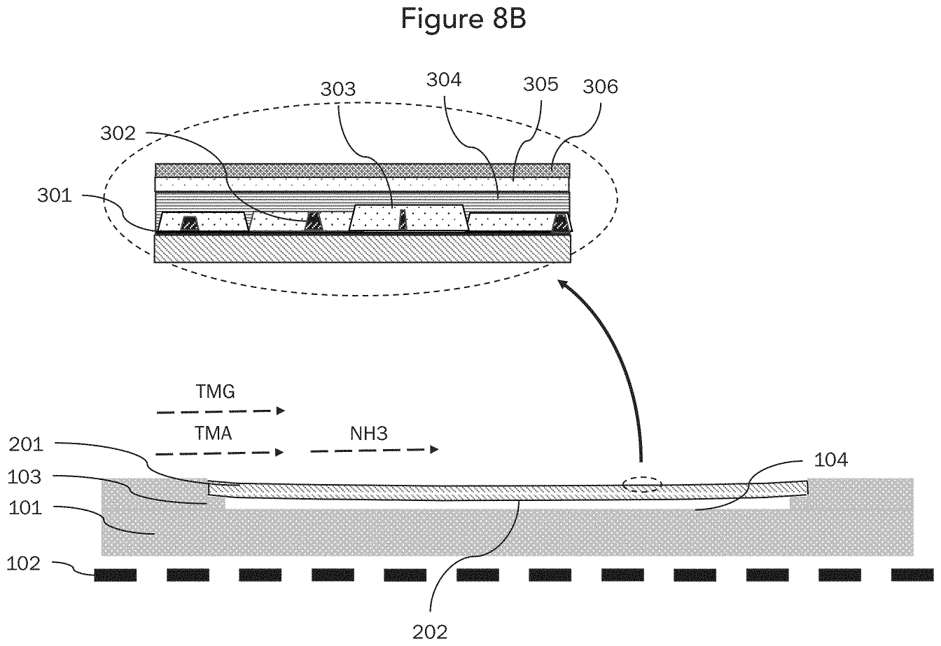

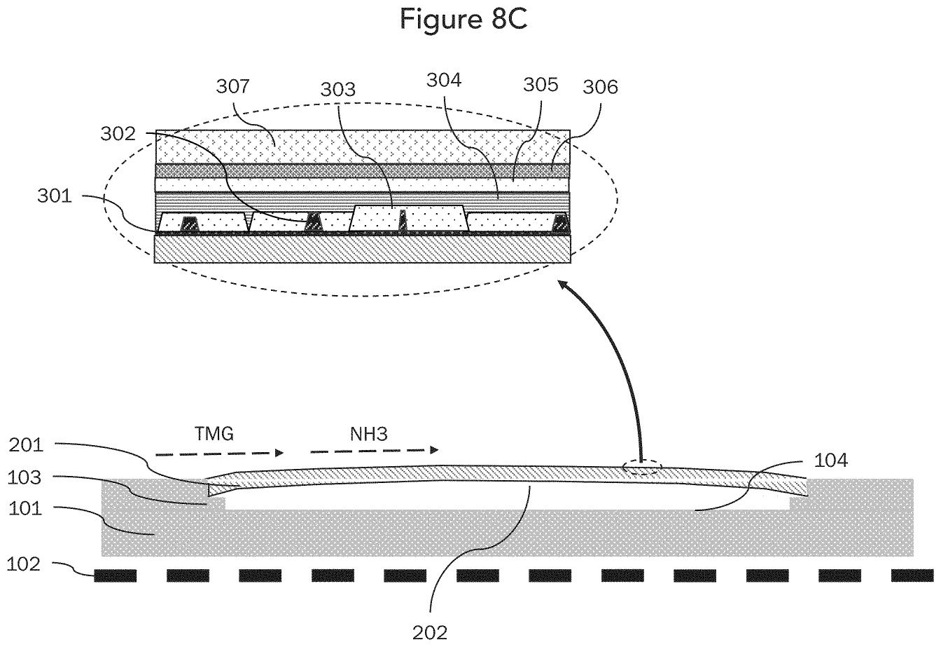

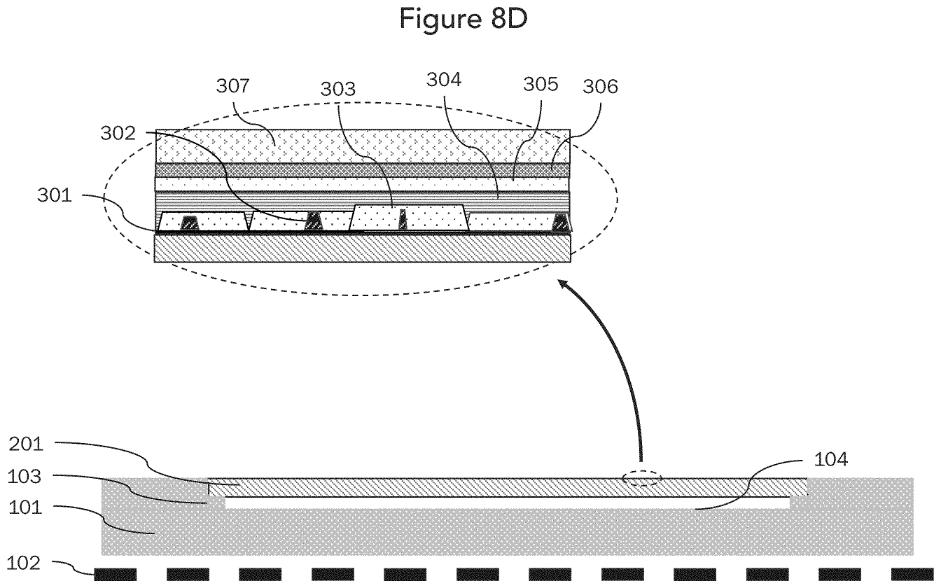

First, the substrate temperature is lowered to a range between 900° C. to 1050° C. As FIG. 8A indicates, a first layer 305 of AlₓGa₁₋ₓN is deposited by flowing Trimethyl-Gallium (TMG) gas into the system where 0<x<1 by adjusting proper flow ratio between TMA and TMG. Because the lattice contact of the AlₓGa₁₋ₓN is larger than that of AlN, it creates an opposite effect as AlN to Si, and tends to cause the substrate to bend upward as shown in FIG. 8A (compared with FIG. 6E). The thickness of this first layer 305 of AlₓGa₁₋ₓN is in the range of 50 nm to 200 nm.

Following the AlₓGa₁₋ₓN layer 305, a second layer 306, of Al_{y}Ga_{1-y}N is deposited by increasing the flow of TMG where y<=x. Because the lattice contact of the Al_{y}Ga_{1-y}N is larger than that of AlₓGa₁₋ₓN, it continues to cause the substrate to bend upward as shown in FIG. 8B. The thickness of this second Al_{y}Ga_{1-y}N layer 306 is in the range of 50 nm to 200 nm.

The purpose of depositing the first AlₓGa₁₋ₓN layer 305, and the second Al_{y}Ga_{1-y}N layer 306 is to shift the resulting surface lattice constant closer to that of GaN, to avoid large density of dislocations generated due to the lattice mismatch between AlN and GaN in the next step of the process.

It should be noted that in embodiments of the present invention where x=y, rather than two different AlGaN layers being grown, in essence only one AlGaN layer is grown on top of the stack of four AlN layers to complete the multi-layer buffer stack.

Finally, the flow of TMA is removed and a layer 307 of GaN is deposited. Usually the thickness of GaN is much thicker than that of the AlN and AlGaN layers to improve the quality of the material. The thickness of GaN layer 307 is between 500 nm and 3000 nm. The quality of the material can be estimated by the linewidth of X-Ray diffraction (XRD) pattern. The narrower XRD linewidth, typically quantified by full-width-at-half-maximum (FWHM), means the higher crystalline quality.

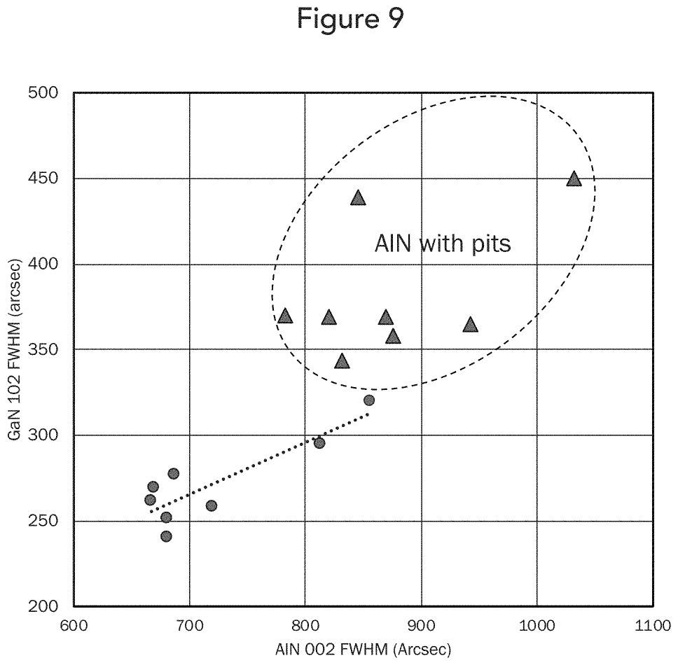

Two data sets of XRD FWHM of GaN and AlN (all data having been obtained by experiments carried out by Applicants) are shown in FIG. 9. The circle data points are measured from the process described by the present invention. It can be seen that the improvements of crystal quality of AlN leads to the improvement of crystal quality of GaN grown on top of it. The reading of 250 arcsecond in this graph corresponding to a dislocation density of ˜2×10⁸ cm⁻².

On the other hand, the triangle data points are measured from the samples where the AlN surface morphology contains pits deeper than 5 nm, as are typically found in similar growth processes prior to the present invention. Not only is the quality of AlN poor, the crystal quality of GaN is correlated with that of AlN, indicating that the pits at the AlN surface are the main cause of poor crystal quality of GaN layer.

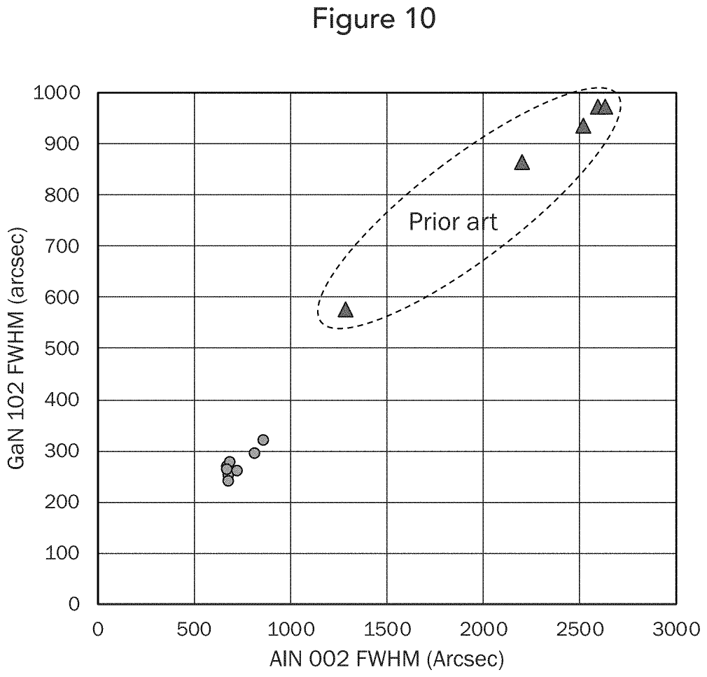

Further, in FIG. 10, the comparison between the XRD results obtained by experiments carried out by Applicants using the present invention and XRD results reported in the prior art (see U.S. Pat. No. 7,598,108) is depicted. The square data points are extracted from the prior art after converting degrees to arcseconds (1 degree=3600 arcseconds). It is clear that the present invention produces far better results.

After the growth, the wafer is cooled down to room temperature. As described in the previous section, the TEC mismatch between AlN/GaN layers and Si causes thermal tensile stress. However, because a compressive stress is developed during the growth, this tensile stress causes the substrate to bow downward and the net stress become small as shown in FIG. 8D.

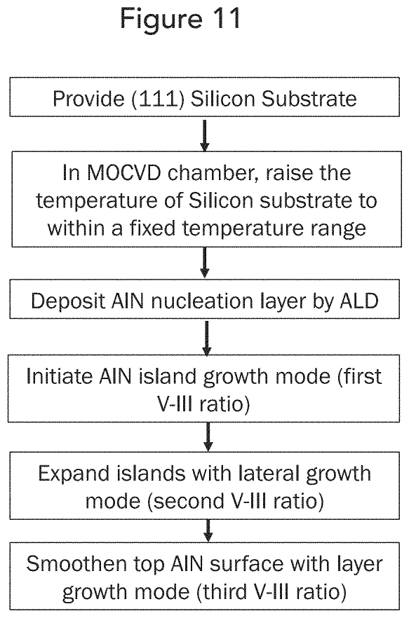

FIG. 11 is a flowchart summarizing the unique 4-step AlN growth process disclosed herein, which allows high quality GaN-based structures to be fabricated on top of the resulting multilayer buffer structure.

The nearly ideal stress management necessary cannot be achieved without a smooth AlN morphology which is enabled by the present invention. In most of the prior art, in order to achieve acceptable crystal quality for device applications, the thicknesses of GaN are generally much thicker. In those approaches, either the substrates break during the growth or the grown films crack after cooling down.

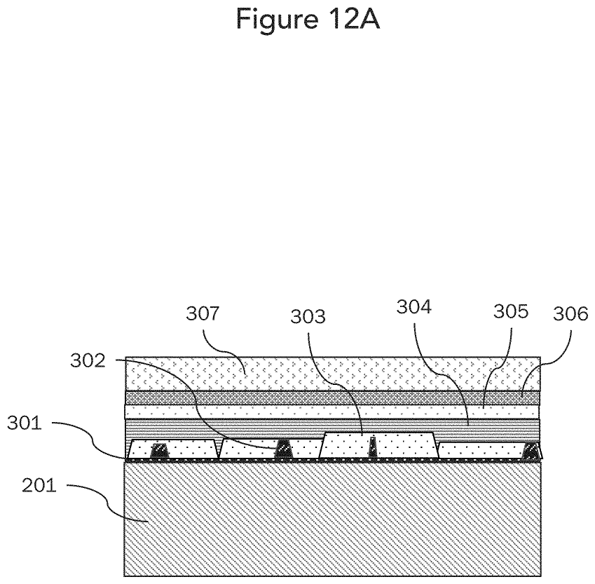

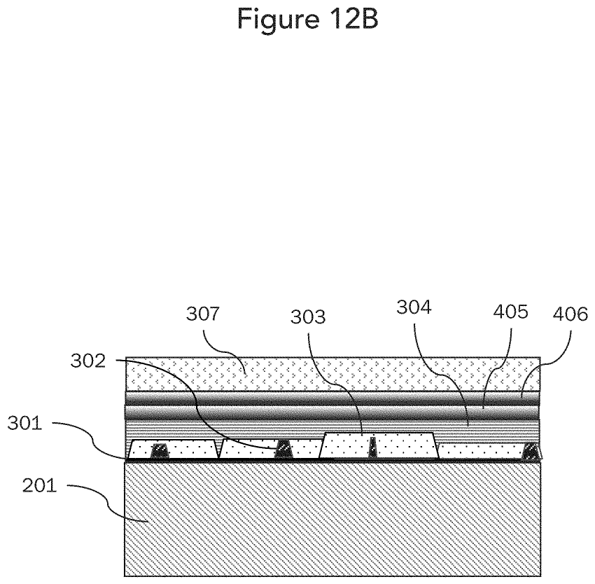

Although stepped AlGaN transition layers are used for lattice constant transition in the process shown in FIG. 11 to create the structure shown in FIG. 12A, for those who are skilled in the art, it is obvious that graded AlGaN materials or superlattice material can be used for the same purpose, the corresponding device cross-section being illustrated in FIG. 12B. In a graded Al_{z}Ga_{1-z}N layer, z varies from high values to low values. The main purpose of both stepped AlGaN transition layers and graded AlGaN transition layers is to adjust the lattice constant from AlN to that of GaN without introducing significant amount of dislocations.

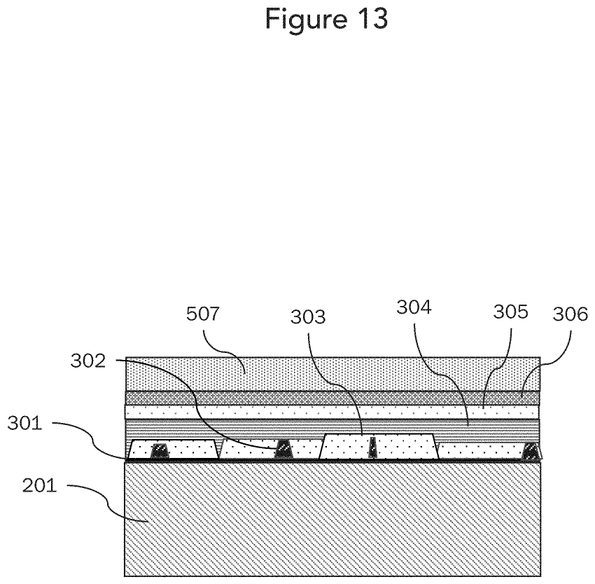

Although in most of this disclosure, the quality of a final GaN layer 307 has been emphasized, for those who are skilled in the art, it is obvious that the present invention can be applied simply to grow high quality AlGaN material on a Si substrate. An exemplary multi-layer buffer structure topped with an epitaxial AlGaN layer 507 is shown in FIG. 13, with applications in devices such as Ultraviolet LEDs or high voltage transistors.

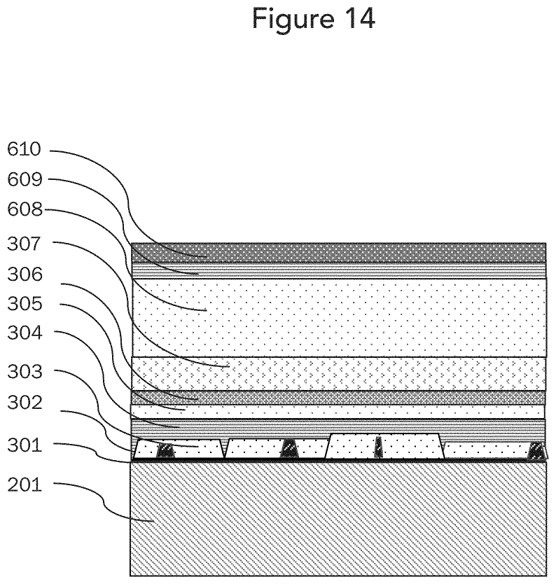

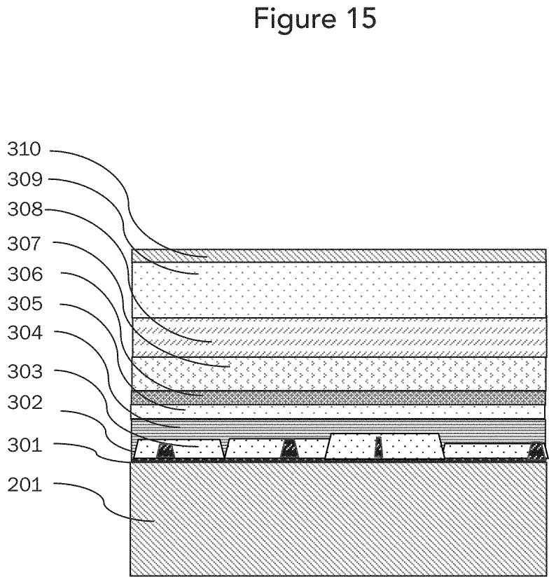

In the present invention, buffer layer structures are described. However, for those of ordinary skill in the art, any additional layers for making devices grown on top of these buffer layers are clearly the main purposes of these buffer layers and should be considered encompassed by the present invention. Without loss of generality, FIG. 14 depicts just one embodiment of using a multi-layer buffer structure of the present invention for a GaN-based LED where n-GaN 608, active region 609 comprising multiple quantum wells, and p-GaN 610 are deposited on top of the stack of buffer layers. Without loss of generality, FIG. 15 depicts one another embodiment of using a multi-layer buffer structure of the present invention for GaN-based High Electron Mobility Transistor (HEMT) in which Carbon-doped GaN 308, undoped GaN 309 and a thin AlGaN layer 310 are deposited on top of the stack of buffer layers. At the interface between the undoped GaN 309 and AlGaN 310, a two-dimensional electron gas is induced due to polarization differences between these two materials.

In conclusion, embodiments of the present invention allow for high quality epitaxial growth of GaN (or GaN-related materials) on a silicon substrate by providing an intervening multi-layer buffer structure including a plurality of layers of AlN. Each of these AlN layers is grown under predetermined different conditions to achieve a desired final stress profile through the structure, and provide an anatomically smooth top surface of the buffer structure. In some cases, just a single layer of AlGaN is grown on top of the plurality of layers of AlN; in other cases, two AlGaN layers of different compositions are grown.

The above-described embodiments should be considered as examples of the present invention, rather than as limiting the scope of the invention. Various modifications will become apparent to those skilled in the art from the foregoing description and accompanying drawings. Accordingly, the present invention is to be limited solely by the scope of the following claims.

1. A method for forming a multi-layer AlN buffer structure on silicon, the method comprising:
providing a (111) oriented silicon substrate having a top surface;
using atomic layer deposition to deposit, at a predetermined temperature range, a first layer of AlN on the top surface;
using first and second precursor materials, characterized by a first V-III ratio, to deposit, at the predetermined temperature range, a plurality of AlN islands forming a second layer overlying and in contact with the first layer;
using the first and second precursor materials, characterized by a second V-III ratio, to deposit, at the predetermined temperature range, a third layer of AlN, the third layer overlying and in contact with the islands and the first layer between the islands, forming domains; and
using the first and second precursor materials, characterized by a third V-III ratio, to deposit, at the predetermined temperature range, a fourth layer of AlN, the fourth layer overlying and in contact with the third layer, wherein the fourth layer is characterized by a fourth layer top surface that is anatomically smooth.

2. The method of claim 1, wherein the substrate has an offcut angle between −1 degree and +1 degree.

3. The method of claim 1, wherein the predetermined temperature range is between 1000° C. and 1200° C.

4. The method of claim 1, wherein the first layer has a thickness between 0.3 nm and 10 nm.

5. The method of claim 1, wherein the first V-III ratio is between 700 and 1000.

6. The method of claim 1, wherein the second V-III ratio is between 300 and 700.

7. The method of claim 1, wherein the third V-III ratio is between 10 and 200.

8. The method of claim 1, wherein the third layer contains multiple crystalline domains.

9. The method of claim 1, wherein the fourth layer has a surface morphology showing layer growth.

10. A method of forming a multi-layer buffer structure on silicon, the method comprising:
providing a (111) oriented silicon substrate having a top surface;
forming on the top surface, at a first temperature range, a first multilayer buffer structure comprising AlN films;
forming on top of the first multilayer buffer structure, at a second temperature range, a second multilayer buffer structure comprising AlGaN films; and
growing, at a third temperature range, a first epitaxial GaN layer directly overlying and in contact with the second multilayer buffer structure;
wherein forming the first multilayer buffer structure comprises:
using atomic layer deposition to deposit a first layer of AlN overlying and in direct contact with the top surface;
using first and second precursor materials, characterized by a first V-III ratio, to deposit a plurality of AlN islands forming a second layer overlying and in contact with the first layer;
using the first and second precursor materials, characterized by a second V-III ratio, to deposit a third layer of AlN, the third layer overlying and in contact with the islands and the first layer between the islands, forming domains; and
using the first and second precursor materials, characterized by a third V-III ratio, to deposit a fourth layer of AlN, the fourth layer overlying and in contact with the third layer, wherein the fourth layer is characterized by a fourth layer top surface that is anatomically smooth;
wherein forming the second multilayer buffer structure comprises:
forming an AlₓGa₁₋ₓN layer directly overlying and in direct contact with the fourth layer of AlN, where 0<x=<0.9; and
forming an Al_{y}Ga_{1-y}N layer directly overlying and in contact with the AlₓGa₁₋ₓN layer, where y<=x.

11. The method of claim 10, wherein the substrate has an off-cut angle between −1 degree and +1 degree.

12. The method of claim 10, wherein the first temperature range is between 1000° C. and 1200° C.

13. The method of claim 10, wherein the first layer has a thickness between 0.3 nm and 10 nm.

14. The method of claim 10, wherein the first V-III ratio is between 700 and 1000, the second V-III ratio is between 300 and 700, and the third V-III ratio is between 10 and 200.

15. The method of claim 10, wherein the third layer contains multiple crystalline domains.

16. The method of claim 10, wherein the third layer of AlN has a surface morphology showing layer growth.

17. The method of claim 10, wherein the second temperature range is between 800° C. and 1100° C.

18. The method of claim 10, wherein the second temperature range is between 900° C. and 1200° C.

19. A multi-layer buffer structure for high quality GaN on a (111) silicon substrate, the structure comprising:
a first AlN layer overlying and in direct contact with the silicon substrate;
a second AlN layer overlying and in direct contact with the first AlN layer;
a third AlN layer overlying and in direct contact with the second AlN layer;
a fourth AlN layer overlying and in direct contact with the third AlN layer; and
a first AlGaN layer overlying and in direct contact with the fourth AlN layer, the first AlGaN layer having a top surface suited for the growth thereupon of high quality GaN;
wherein the second AlN layer comprises multiple crystal domains formed by island growth over the first AlN layer.

20. The multi-layer buffer structure of claim 19, further comprising:
a second AlGaN layer overlying and in direct contact with the first AlGaN layer; the second AlGaN layer having a top surface suited for the growth thereupon of high quality GaN.
